(19) United States
(12) Patent Application Publication
(10) Pub. No.: US 2022/0056314 A1
(43) Pub. Date: Feb. 24, 2022

(54) Adhesive film for display

(71) Applicant: INNOX ADVANCED MATERIALS CO., LTD., Asan-si (KR)

(72) Inventors: JONG HOON LEE, Asan-si (KR); Hyung Jin KIM, Asan-si (KR); Jong Geol LEE, Asan-si (KR); MYUNG SUP JUNG, Asan-si (KR)

(21) Appl. No.: 17/407,924

(22) Filed: Aug. 20, 2021

(30) Foreign Application Priority Data
Aug. 21, 2020 (KR) 10-2020-0105098

(51) Int. Cl. C09J 7/29; C09J 7/30; C09J 7/40; C09J 7/25; C09J 11/04; C09J 11/06

(52) U.S. Cl. CPC C09J 7/29; C09J 7/30; C09J 7/405; C09J 7/255; C09J 11/04; C09J 11/06; G02B 5/208; C09J 2301/408; C09J 2433/00; C09J 2475/00; C09J 2463/00; C09J 2483/00; C09J 2467/006; C09J 2203/326

(57) ABSTRACT

Provided is an adhesive film for a display, in which the adhesive film has a high absorption capacity in a near infrared region and maintains a high transmittance in a visible region, thereby guaranteeing visibility.

### CROSS REFERENCE TO RELATED APPLICATION

The present application claims priority to Korean Patent Application No. 10-2020-0105098, filed Aug. 21, 2020, the entire contents of which is incorporated herein for all purposes by this reference.

### BACKGROUND OF THE INVENTION

### Field of the Invention

The present invention relates to an adhesive film for a display, and more particularly, to an adhesive film for a display, which has a high absorption capacity in a near infrared region and maintains a high transmittance in a visible region, thus guaranteeing visibility.

### Description of the Related Art

Recently, in the display industry, an adhesive film has been required which absorbs near infrared light and has superior visible transmittance.

Conventionally, an adhesive film having a superior visible transmittance and an excellent transmittance with respect to near infrared light in a low wavelength band of 800 nm through 1000 nm has been developed, but visibility may be degraded due to a high transmittance with respect to near infrared light in the low wavelength band. Moreover, conventionally, indium tin oxide (ITO) has been used to improve visibility, but an absorption capacity of near infrared light is insufficient and photopigmentation occurs due to ultraviolet light, degrading a visible transmittance. To solve such problems, there is a need for an adhesive film that lowers a near infrared transmittance and maintains a high transmittance in the visible region.

### SUMMARY OF THE INVENTION

The present invention is proposed to solve these problems and aims to provide an adhesive film for a display, which has a transmittance of 80% or more with respect to visible light in a wavelength band of 400 nm through 800 nm and a transmittance of 5% through 50% with respect to near infrared light in a wavelength band exceeding 800 nm up to 1500 nm.

However, technical objects to be achieved by the present invention are not limited to the objects mentioned above, and other unmentioned objects would be apparently understood by those of ordinary skill in the art from the following description.

According to an embodiment of the present invention, an adhesive film for a display is manufactured by curing a composition including adhesive resin and a near infrared light blocking agent, and has a transmittance of 80% or more with respect to visible light in a wavelength band of 400 nm through 800 nm and a transmittance of 5% through 50% with respect to near infrared light in a wavelength band exceeding 800 nm up to 1500 nm.

### BRIEF DESCRIPTION OF THE DRAWINGS

FIG. 1 is a cross-sectional view illustrating an adhesive film for a display, according to an embodiment of the present invention.

FIG. 2 is a cross-sectional view illustrating an adhesive film for a display, according to another embodiment of the present invention.

FIG. 3 is a cross-sectional view illustrating an adhesive film for a display, according to another embodiment of the present invention.

### DETAILED DESCRIPTION OF THE INVENTION

The objects, specific advantages, and novel features of the present invention will become more apparent from the following detailed description taken in conjunction with the accompanying drawings. In this specification, terms such as “a surface”, “the other surface”, “both surfaces”, etc., are used to distinguish one component from another component, and the component is not limited by the terms. Hereinafter, in describing the present invention, detailed descriptions of related known technologies that may unnecessarily obscure the subject matter of the present invention will be omitted.

An adhesive film for a display according to the present invention may be manufactured by curing a composition including adhesive resin and a near infrared light blocking agent, and may have a transmittance of 80% or more with respect to visible light in a wavelength band of 400 nm through 800 nm and a transmittance of 5% through 50% with respect to near infrared light in a wavelength band exceeding 800 nm up to 1500 nm.

First, a composition for manufacturing an adhesive film for a display according to the present invention may include adhesive resin.

The adhesive resin may include urethane resin, acrylic resin, epoxy resin, silicone resin, or a combination thereof.

The urethane resin may include urethane (meth)acrylate resin, 1,2-polybutadiene-terminal urethane (meth)acrylate resin, 1,4-polybutadiene-terminal urethane (meth)acrylate resin, polyester-based urethane (meth)acrylate resin, polyether-based urethane (meth)acrylate resin, their respective hydrophilic-group substitutions, their respective hydrogenated additives, or a combination thereof. The urethane (meth)acrylate resin may have been manufactured by reacting polyisocyanate, polyol, and (meth)acrylic acid with one another.

The polyisocyanate may include 2,4-tolylene diisocyanate, 2,6-tolylene diisocyanate, 4,4′-diphenylmethane diisocyanate, m-phenylene diisocyanate, xylylene diisocyanate, tetramethylene diisocyanate, hexamethylene diisocyanate, lysine diisocyanate ester, 1,4-cyclohexylene diisocyanate, 4,4′-dicyclohexylmethane diisocyanate, 3,3′-dimethyl-4,4′-biphenylene diisocyanate, or a combination thereof.

The polyol may include polyesterdiol, polyetherdiol, polycaprolactonediol, polycarbonatediol, or a combination thereof.

The acrylic resin may include monofunctional (meth)acrylate resin, polyfunctional (meth)acrylate resin, or a combination thereof. The monofunctional (meth)acrylate resin may include methyl (meth)acrylate, ethyl (meth)acrylate, propyl (meth)acrylate, butyl (meth)acrylate, 2-ethylhexyl (meth)acrylate, isooctyl (meth)acrylate, isodecyl (meth)acrylate, lauryl (meth)acrylate, stearyl (meth)acrylate, phenyl (meth)acrylate, cyclohexyl (meth)acrylate, dicyclopentanyl (meth)acrylate, dicyclopentenyl (meth)acrylate, dicyclopentenyloxyethyl (meth)acrylate, isobornyl (meth)acrylate, methoxylation cyclodecatriene (meth)acrylate, 2-hydroxyethyl (meth)acrylate, 2-hydroxypropyl (meth)acrylate, 3-hydroxypropyl (meth)acrylate, 4-hydroxybutyl (meth)acrylate, tetrahydrofurfuryl (meth)acrylate, 2-hydroxy-3-phenoxypropyl (meth)acrylate, glycidyl (meth)acrylate, caprolactone-modified tetrahydrofurfuryl (meth)acrylate, 3-chloro-2-hydroxypropyl (meth)acrylate, N,N-dimethylaminoethyl (meth)acrylate, N,N-diethylaminoethyl (meth)acrylate, t-butylaminoethyl (meth)acrylate, ethoxycarbonylmethyl (meth)acryl rate, phenol ethylene oxide modified acrylate, phenol (modified by 2 moles of ethylene oxide) acrylate, phenol (modified by 4 moles of ethylene oxide) acrylate, paracumylphenol ethylene oxide modified acrylate, nonylphenol ethylene oxide modified acrylate, nonylphenol (modified by 4 moles of ethylene oxide) acrylate, nonylphenol (modified by 8 moles of ethylene oxide) acrylate, nonylphenol (modified by 2.5 moles of propylene oxide) acrylate, 2-ethylhexylcar bitol acrylate, ethylene oxide-modified phthalic acid (meth)acrylate, ethylene oxide-modified succinic acid (meth)acrylate, trifluoroethyl (meth)acrylate, acrylic acid, methacrylic acid, maleic acid, fumaric acid, ω-carboxy-polycaprolactone mono (meth)acrylate, monohydroxyethyl phthalate (meth)acrylate, (meth)acrylic acid dimer, β-(meth)acroyloxyethyl hydrogen succinate, n-(meth)acryloyloxy alkyl hexahydrophthalimide, and a polymer of one or more monomers selected from a group consisting of their hydrophilic-group substitutions.

The polyfunctional (meth)acrylate resin may include a bifunctional (meth)acrylate resin, a trifunctional (meth)acrylate resin, a tetrafunctional or higher-functional (meth)acrylate resin, or a combination thereof.

The bifunctional (meth)acrylate resin may include 1,3-butylene glycol di(meth)acrylate, 1,4-butanediol di(meth)acrylate, 1,6-hexadiol di(meth)acrylate, 1,9-nonanediol di(meth)acrylate, neopentyl glycol di(meth)acrylate, dicyclopentanyl di(meth)acrylate, 2-ethyl-2-butyl-propanediol (meth)acrylate, neopentyl glycol modified trimethylolpropane di(meth)acrylate, stearic acid modified pentaerythritol diacrylate, polypropylene glycol di(meth)acrylate, 2,2-bis(4-(meth)acryloxydiethoxyphenyl) propane, 2,2-bis(4-(meth)acryloxypropoxyphenyl)propane, 2,2-bis(4-(meth)acryloxytetraethoxyphenyl)propane, and a polymer of one or more monomers selected from a group consisting of their hydrophilic-group substitutions.

The trifunctional (meth)acrylate resin may include trimethylolpropane tri(meth)acrylate, tris[(meth)acryloxyethyl]isocyanurate, and a polymer of one or more monomers selected from a group consisting of their hydrophillic-group substitutions.

The tetrafunctional or higher-functional (meth)acrylate resin may include dimethylolpropane tetra (meth)acrylate, pentaerythritol tetra (meth)acrylate, pentaerythritol ethoxy tetra (meth)acrylate, dipentaerythritol penta (meth)acrylate, dipentaerythritol hexa (meth)acrylate, and a polymer of one or more monomers selected from a group consisting of their hydrophillic-group substitutions.

The epoxy resin may include bisphenol-based epoxy resin, biphenyl-based epoxy resin, naphthalene-based epoxy resin, fluorene-based epoxy resin, phenol novolak-based epoxy resin, cresol novolak-based epoxy resin, trishydroxylphenylmethane-based epoxy resin, tetraphenylmethane-based epoxy resin, or a combination thereof. In this case, the bisphenol-based epoxy resin may include bisphenol A-type epoxy resin, bisphenol F-type epoxy resin, bisphenol S-type epoxy resin, hydrogenated bisphenol A-type epoxy resin, bisphenol AF-type epoxy resin, etc. As epoxy-based resin, products of bisphenol A-type epoxy resin currently on the market may include YD-020, YD-020L, YD-019K, YD-019, YD-017H, YD-017R, YD-017, YD-014, YD-014ER, YD-013K, YD-012, YD-011H, YD-011S, YD-011 of Kukdo Chemical Co., Ltd., etc. As cresol novolak-based epoxy resin, there are YDCN-500-80PCA60, YDCN-500-80PBC60, YDCN-500-90PA75, YDCN-500-90P, YDCN-500-80P, YDCN-500-10P, YDCN-500-8P, YDCN-500-7P, YDCN-500-5P, YDCN-500-4P, and YDCN-500-1P of Kukdo Chemical Co., Ltd. EOCN-1025, EOCN-1035, EOCN-1045, EOCN-1012, EOCN-1025, and EOCN-1027 of Nippon Kayaku Co., Ltd., YDCN-701, YDCN-702, YDCN-703, YDCN-704, YDCN-701P, YDCN-702P, YDCN-703P, YDCN-704P, YDCN-7015, YDCN-7025, and YDCN-703S of Dongdo Chemical Co., Ltd., and so forth. As phenol novolak-based epoxy resin, there are YDPN-638A80, YDPN-644, YDPN-637, YDPN-636, YDPN-638, YDPN-631, etc.

The silicone resin may include solvent addition resin, solvent condensation resin, solvent UV-curable resin, solvent-free addition resin, solvent-free condensation resin, solvent-free UV-curable resin, solvent-free electron beam curing resin, or a combination thereof.

Next, the composition for manufacturing the adhesive film for the display according to the present invention may include a near infrared blocking agent.

The composition may include 0.5 to 8 parts by weight of the near infrared blocking agent with respect to 100 parts by weight of the adhesive resin, thereby suppressing transmission of near infrared light and thus improving a visible transmittance.

The near infrared blocking agent may include metal oxide nano powder, near infrared dye, or a combination thereof. The metal oxide nano powder may include indium tin oxide (ITO), tungsten trioxide (WO₃), cesium-doped WO₃ (CWO), or a combination thereof. Preferably, as the metal oxide nano powder, one or more of CWO and WO₃ may be used together with ITO. The ITO may absorb a long wavelength of 1200 nm to 1500 nm. In addition, CWO and WO₃ may absorb a wavelength exceeding 800 nm up to 1500 nm. Preferably, to secure visibility while maintaining transparency of an adhesive film with a high efficiency in a visible region, diameters of particles of the ITO, CWO, and WO₃ may range from 10 nm to 100 nm.

The near infrared blocking agent may more efficiently block transmission of near infrared light by including near infrared dye. The near infrared dye may include a cyanine-based compound, a phthalocyanine-based compound, a naphthalocyanine-based compound, a porphyrin-based compound, a benzoporphyrin-based compound, a scaryllium-based compound, an anthraquinone-based compound, a croconium-based compound, a dimonium-based compound, a dithiol metal complex, or a combination thereof, and may have a maximum absorption wavelength in a wavelength band exceeding 800 nm up to 1200 nm.

Next, a composition of a near infrared blocking adhesive film according to the present invention may further include 0.1 to 10 parts by weight of a thermosetting agent with respect to 100 parts by weight of the adhesive resin. As the composition includes the thermosetting agent in the foregoing range, thermosetting of the composition may be accelerated.

The thermosetting agent may include iodonium salt such as diphenyliodonium⋅hexafluorophosphate, diphenyliodonium⋅hexafluoroantimonate, diphenyliodonium⋅tetrafluoroborate, diphenyliodonium⋅tetrakis(pentafluorophenyl)borate, bis(dodecylphenyl)iodonium⋅hexafluorophosphate, bis(dodecylphenyl)iodonium⋅hexafluoroantimonate, bis(dodecylphenyl)iodonium⋅tetrafluoroborate, bis(dodecylphenyl)iodonium⋅tetrakis(pentafluorophenyl)borate, 4-methylphenyl-4-(1-methylethyl)phenyliodonium⋅hexafluorophosphate, 4-methylphenyl-4-(1-methylethyl)phenyliodonium⋅hexafluoroantimonate, 4-methylphenyl-4-(1-methylethyl)phenyliodonium⋅tetrafluoroborate, 4-methylphenyl-4-(1-methylethyl)phenyliodonium⋅tetrakis(pentafluorophenyl)borate, 4-methoxydiphenyliodonium⋅hexafluorophosphate, bis(4-methylphenypiodonium⋅hexafluorophosphate, bis(4-t-butylphenyl)iodonium⋅hexafluorophosphate, bis(dodecylphenyl)iodonium⋅trilcumyliodonium hexafluorophosphate, etc.; sulfonium salt such as triallylsulfonium hexafluoroantimonate, etc.; phosphonium salt such as triphenylpyrenylmethylphosphonium salt, etc.; (η6-benzene) (η5-cyclopentadienyl)iron(II)hexafluoroantimonate; a combination of o-nitrobenzylsilyl ether and aluminum acetylacetonate; a combination of silsesquioxane and aluminum acetylacetonate; melamine-based resin; organic peroxide (e.g., ketone peroxide, peroxyketal, diacyl peroxide, peroxyester, peroxydicarbonate, etc.), Lewis acid (boron trifluoride, zinc chloride, aluminum chloride, iron chloride, tin chloride, etc.), azo compounds (azobisisobutyronitrile, 1,1′-azobis(cyclohexanecarbonitrile), etc.), acid (organic acid or sulfonium salt-based acid generator that generates acid by low-temperature heating), a base (polyamine such as aliphatic polyamine, amine compounds such as imidazole, hydrazide and ketimine, etc., and compounds that generate amine compounds by heating at low temperature, etc.), polyamide resin, polymercaptan, platinum group metal compound or its complex (platinum chloride (IV), chloroplatinic acid hexahydrate, bis(alkynyl)bis(triphenylphosphine)platinum complex, etc.), or a combination thereof. A product on the market of the thermosetting agent may include 45S (BuRim Chemical, Co., Ltd.) and DS-HF 10929TKI CATALYST (manufactured by Tekoku Ink manufacturer, melamine resin).

Next, the composition of the near infrared blocking adhesive film according to the present invention may further include 0.1 to 10 parts by weight of a photopolymerization initiator with respect to 100 parts by weight of the adhesive resin. As the composition includes the photopolymerization initiator in the foregoing range, curing of the composition based on infrared irradiation may be accelerated.

The photopolymerization initiator may include benzophenone or its derivative, benzyl or its derivative, anthraquinone or its derivative, benzoin, a benzoin derivative such as benzoin methyl ether, benzoin ethyl ether, benzoin propyl ether, benzoin isobutyl ether, benzyl dimethyl ketal, etc., an acetophenone derivative such as diethoxyacetophenone, 4-t-butyltrichloroacetophenone, etc., 2-dimethylaminoethylbenzoate, p-dimethylaminoethylbenzoate, diphenyldisulfide, thioxanthone and derivatives thereof, camphorquinone; a camphorquinone derivative such as 7,7-dimethyl-2,3-dioxobicyclo[2.2.1]heptane-1-carboxylic acid, 7,7-dimethyl-2,3-dioxobicyclo[2.2.1]heptane-1-carboxy-2-bromoethyl ester, 7,7-dimethyl-2,3-dioxobicyclo[2.2.1]heptane-1-carboxy-2-methyl ester, 7,7-dimethyl-2,3-dioxobicyclo[2.2.1] heptane-1-carboxylic acid chloride, etc.; an α-aminoalkylphenone derivative such as 2-methyl-1-[4-(methylthio)phenyl]-2-morpholinopropan-1-one, 2-benzyl-2-dimethylamino-1-(4-morpholinophenyl)-butanone-1, etc.;

an acyl phosphine oxide derivative such as benzoyldiphenylphosphine oxide, 2,4,6-trimethylbenzoyldiphenylphosphine oxide, benzoyldiethoxyphosphine oxide, 2,4,6-trimethylbenzoyldimethoxyphenylphosphine oxide, 2,4,6-trimethylbenzoyldiethoxyphenylphosphine oxide, etc., or a combination thereof.

A composition for manufacturing an adhesive film for a display according to the present invention may include 1 to 15 parts by weight of an ultraviolet blocking agent with respect to 100 parts by weight of the adhesive resin, thereby suppressing transmission of infrared light and thus improving a visible transmittance. The ultraviolet blocking agent may include an ultraviolet absorbent, a light stabilizer, and an antioxidant.

As the composition includes the ultraviolet absorbent, temperature may increase due to ultraviolet light, suppressing photopigmentation in which physical properties of the adhesive film are changed or a transmittance is degraded due to ultraviolet light for a long term. The ultraviolet absorbent may include an organic ultraviolet absorbent such as a benzotriazole compound, a benzophenone compound, a salicylic acid compound, a triazine compound, a benzotriazolyl compound, a benzoyl compound, etc., an inorganic ultraviolet absorbent such as zinc oxide, titanium oxide, cerium oxide, etc., or a combination thereof. Preferably, as the ultraviolet absorbent includes a benzotriazole compound, a benzophenone compound, or a combination thereof, durability with respect to ultraviolet light may be improved while maintaining a visible transmittance high.

As the composition includes the light stabilizer, occurrence of photopigmentation may be suppressed and degradation of the ultraviolet absorbent may be prevented, contributing to maintenance of performance of the ultraviolet absorbent. The light stabilizer may be a hindered amine light stabilizer (HALs), and for example, bis(2,2,6,6-tetramethyl-4-piperidyl)sebacate, bis(1,2,2,6,6-pentamethyl-4-piperidyl)sebacate, 1-[2-[3-(3,5-t-butyl-4-hydroxyphenyl)propionyloxy]ethyl]-4-[3-(3,5-di-t-butyl-4-hydroxyphenyl)propionyl oxy]-2,2,6,6-tetramethylpiperidine,4-benzoyloxy-2,2,6,6-tetramethylpiperidine, 8-acetyl-3-dodecyl-7,7,9,9-tetramethyl-1,3,8-triazaspiro[4,5]decane-2,4-dione, bis-(1,2,2,6,6-pentamethyl-4-piperidyl)-2-(3,5-di-t-butyl-4-hydroxybenzyl)-2-n-butylmalonate, tetrakis (1,2,2,6,6-pentamethyl-4-piperidyl)-1,2,3,4-butanetetracarboxylate), tetrakis(2,2,6,6-tetramethyl-4-piperidyl)-1,2,3,4-butanetetracarboxylate), (mixed 1,2,2,6,6-pentamethyl-4-piperidyl/tridecyl)-1,2,3,4-butanetetracarboxylate, mixed {1,2,2,6,6-pentamethyl-4-piperidyl/β,β,β′,β′-tetramethyl-3,9-[2,4,8,10-tetraoxaspiro (5,5)undecane]diethyl}-1,2,3,4-butanetetracarboxylate, mixed 2,2,6,6-tetramethyl-4-piperidyl/tridecyl)-1,2,3,4-butanetetracarboxylate, mixed {2,2,6,6-tetramethyl-4-piperidyl/β,β,β′,β′-tetramethyl-3,9-[2,4,8,10-tetraoxaspiro (5,5) undecane]diethyl}-1,2,3,4-butanetetracarboxylate, 2,2,6,6-tetramethyl-4-piperidyl methacrylate, 1,2,2,6,6-pentamethyl-4-piperidyl methacrylate, poly[(6-(1,1,3,3-tetramethylbutyl)imino-1,3,5-triazine-2,4-diyl)][(2,2,6,6-tetramethyl-4-piperidyl)imino]hexamethylene[(2,2,6,6-tetramethyl-4-piperidyl)iminol], a polymer of dimethyl succinate and 4-hydroxy-2,2,6,6-tetramethyl-1-piperidineethanol, N,N′,N″,N′″-tetrakis-(4,6-bis-(butyl-(N-methyl-2,2,6,6-tetramethylpiperidin-4-yl)amino)-triazin-2-yl)-4,7-diazadecane-1,10-diamine, a polycondensate of dibutylamine-1,3,5-triazine-N,N′-bis(2,2,6,6-tetramethyl-4-piperidyl-1,6-hexamethylenediamine and N-(2, 2,6,6-tetramethylpiperidyl)butylamine, decanoic acid bis(2,2,6,6-tetramethyl-1-(octyloxy)-4-piperidyl)ester, etc.

As the composition includes the antioxidant, oxidation and degradation of the adhesive film may be suppressed, thereby improving weather-proofness of the adhesive film. For example, as the antioxidant, a phenol-based antioxidant, a sulfur-based antioxidant, a phosphorus-based antioxidant, etc., may be properly used depending on needs. As the antioxidant, more specifically, there may be 2,6-di-t-butyl-p-cresol, butylated hydroxyanisole, 2,6-di-t-butyl-4-ethylphenol, stearyl-β-(3,5-di-t-butyl-4-hydroxyphenyl)propionate, 2,2′-methylenebis-(4-methyl-6-butylphenol), 2,2′-methylenebis-(4-ethyl-6-t-butylphenol), 4,4′-butylidene-bis-(3-methyl-6-t-butylphenol), 1,1,3-tris-(2-methyl-hydroxy-5-t-butylphenyl)butane, tetrakis[methylene-3-(3′,5′-butyl-4-hydroxyphenyl)propionate]methane, 1,3,3-tris-(2-methyl-4-hydroxy-5-t-butylphenol)butane, 1,3,5-trimethyl-2,4,6-tris(3,5-di-t-butyl-4-hydroxybenzyl)benzene, bis(3,3′-t-butylphenol)butyric acid glycol ester, isooctyl-3-(3,5-di-t-butyl-4-hydroxyphenyl)propionate, and so forth.

The composition may include 0.02 through 5 parts by weight of the ultraviolet absorbent, 0.05 through 5 parts by weight of the light stabilizer, and 0.05 through 5 parts by weight of the antioxidant, with respect to 100 parts by weight of the adhesive resin. The composition may include 0.02 through 5 parts by weight of the ultraviolet absorbent with respect to 100 parts by weight of the adhesive resin, thereby preventing the ultraviolet absorbent from being precipitated, not affecting transparency and designability of the adhesive film, and sufficiently absorbing ultraviolet light. The composition may include 0.05 through 5 parts by weight of the light stabilizer with respect to 100 parts by weight of the adhesive resin, thereby sufficiently exhibiting the effect of the light stabilizer, preventing the light stabilizer from being precipitated from the adhesive film, and not affecting transparency and designability of the adhesive film. The composition may include 0.05 through 5 parts by weight of the antioxidant with respect to 100 parts by weight of the adhesive resin, thereby sufficiently exhibiting the effect of addition of the antioxidant in the adhesive film, preventing the light stabilizer from being precipitated from the adhesive film, and not affecting transparency and designability of the adhesive film.

In addition, the composition for manufacturing the adhesive film for the display according to the present invention may include, depending on needs, a polymerization inhibitor such as methylhydroquinone, hydroquinone, 2,2-methylene-bis(4-methyl-6-tertbutylphenol), catechol, hydro-8-quinone monomethylether, mono-tertbutylhydroquinone, 2,5-di-tertbutylhydroquinone, p-benzoquinone, 2,5-diphenyl-p-benzoquinone, 2,5-di-tertbutyl-p-benzoquinone, picric acid, citric acid, phenothiazine, tertbutylcatechol, 2-butyl-4-hydroxyanisole, 2,6-di-tertbutyl-p-cresol, etc.; various elastomers such as acrylic rubber, urethane rubber, acrylonitrile-butadiene-styrene rubber, etc.; an inorganic filler; an extender; an reinforcement; a plasticizer; a thickener; an additional dye; a pigment; a flame retardant; a silane coupling agent; a surfactant, or a combination thereof.

In particular, the adhesive film, which is a cured article of the composition according to the present invention, may have a transmittance of 80% or more with respect to visible light in a wavelength band of 400 nm through 800 nm and a transmittance of 5% through 50% with respect to near infrared light in a wavelength band exceeding 800 nm up to 1500 nm.

More specifically, the adhesive film may have a transmittance of 10% through 50% with respect to near infrared light in a wavelength band exceeding 800 nm up to 1000 nm. Herein, the visible transmittance may have been obtained by measuring a wavelength-specific transmittance in a wavelength band of 400 nm through 800 nm using a UV-Vis-NIR spectrometer (Perkin Elmer, Lambda 1050+) and then averaging the measured values. The near infrared transmittance may have been obtained by measuring a wavelength-specific transmittance in a specific wavelength band from a wavelength band exceeding 800 nm up to 1500 nm using a UV-Vis-NIR spectrometer (Perkin Elmer, Lambda 1050+) and then averaging the measured values.

A spectral wavelength of sunlight is a unique characteristic of a material, and generally, an ultraviolet wavelength band may from 280 nm to less than 400 nm, the visible wavelength band may be from 400 nm to 800 nm, and the near infrared wavelength band may exceed 800 nm up to 1500 nm. In particular, a region affecting visibility may be from 400 nm to 800 nm, and may be recognized as red, green, and blue.

Herein, with the metal oxide nano powder included in the near infrared blocking agent of the adhesive film for the display according to the present invention, near infrared light in a wavelength band exceeding 800 nm up to 1500 nm may be blocked. In particular, the adhesive film for a display according to the present invention may efficiently block near infrared light of a long wavelength exceeding 1000 nm with the ITO included in the near infrared blocking agent. In addition, near infrared light in a wavelength band exceeding 800 nm up to 1200 nm may be efficiently blocked by the near infrared dye included in the near infrared blocking agent. Thus, the adhesive film for the display according to the present invention may selectively transmit visible light in a wavelength band of 400 nm to 800 nm out of the spectral wavelength of sunlight. That is, the adhesive film for the display according to the present invention may efficiently block the near infrared wavelength of sunlight, and a transmittance of 80% or more with respect to visible light in a wavelength band of 400 nm to 800 nm may be implemented, thereby more efficiently improving visibility.

Next, the adhesive film for the display according to the present invention may have any one or more of a release film, a transparent base film, and glass attached to a surface or both surfaces thereof.

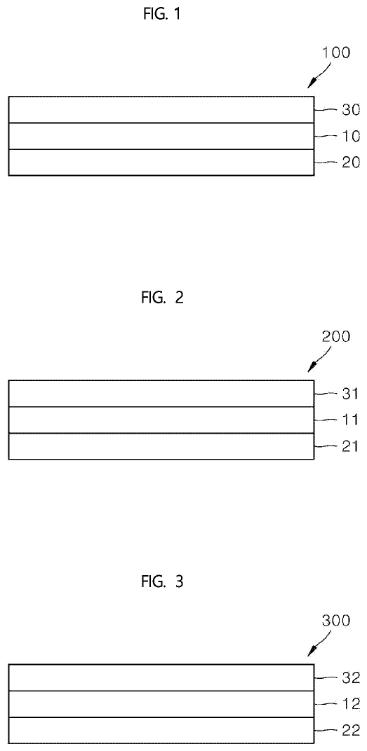

FIG. 1 is a cross-sectional view illustrating an adhesive film 100 a display, according to an embodiment of the present invention.

Referring to FIG. 1, the adhesive film 100 for the display may include a first release film 20 formed on a surface of the adhesive film 10 and a second release film 30 formed on the other surface of the adhesive film 10. For the adhesive film 100 for the display, after the first release film 20 and the second release film 30 are separated from the adhesive film 10, the adhesive film 10 may be used.

FIG. 2 is a cross-sectional view illustrating an adhesive film 200 for a display, according to an embodiment of the present invention.

Referring to FIG. 2, the adhesive film 200 for the display may include a transparent base film 21 formed on a surface of an adhesive film 11 and a release film 31 formed on the other surface of the adhesive film 11. For example, the transparent base film may include polyethylene terephthalate (PET), triacetyl cellulose (TAC), cycloolefin polymer (COP), polycarbonate (PC), polyethersulfone (PES), polypropylene (PP), acryl, or a combination thereof.

For the adhesive film 200 for the display, the release film 31 may be separated from the adhesive film 11, and the adhesive film 11 and the transparent base film 21 may be used as being attached to each other.

Preferably, the transparent base film 21 may further include any one of an anti-reflection layer, a low-reflection layer, and a hard coating layer, thereby reducing light reflected from the adhesive film 11 and further improving visibility by removing faint light.

FIG. 3 is a cross-sectional view illustrating an adhesive film 300 for a display, according to another embodiment of the present invention.

Referring to FIG. 3, the adhesive film 300 for the display may include a transparent base film 22 formed on a surface of an adhesive film 12 and glass 32 formed on the other surface of the adhesive film 12. For example, the transparent base film 22 may include PET, TAC, COP, PC, PES, PP, acryl, or a combination thereof. Preferably, at least one of the transparent base film 22 and the glass 32 may further include an anti-reflection layer, a low-reflection layer, and a hard coating layer, thereby reducing light reflected from the adhesive film 12 and further improving visibility by removing faint light.

The adhesive film for the display according to the present invention may be applied to a display device. For example, the display device may include a circuit device, a liquid crystal display panel, an organic light-emitting diode panel, etc.

Hereinbelow, to help understanding of the present invention, a preferred embodiment will be proposed. However, the following embodiment is provided to facilitate understanding of the present invention, and the present invention is not limited by the following embodiment.

### Embodiment

Manufacture Composition for Manufacturing Adhesive Film

A composition for manufacturing an adhesive film has been manufactured by mixing adhesive resin (AR), one or more kinds of near infrared blocking agents (NIR-A), and a curing agent (PI). A type and a content of each ingredient have been described in Table 1.

TABLE 1

| | | NIR-A | | | | |
|---|---|---|---|---|---|---|
| | AR | NIR-A1 | NIR-A2 | NIR-A3 | NIR-A4 | PI |
| Embodiment 1 | 100 | 1 | 1 | 0.5 | 0.5 | 1 |
| Embodiment 2 | 100 | 1 | 1 | 0.5 | 1 | 1 |
| Embodiment 3 | 100 | 0.5 | 1 | 1 | 1 | 1 |
| Embodiment 4 | 100 | 4 | 1 | 1 | 1 | 1 |
| Embodiment 5 | 100 | 4 | — | — | 1 | 1 |
| Embodiment 6 | 100 | — | 4 | — | 1 | 1 |
| Embodiment 7 | 100 | 1 | 1 | — | 0.5 | 1 |
| Embodiment 8 | 100 | 1 | 1 | — | 0.5 | 1 |
| Embodiment 9 | 100 | 0.5 | 1 | — | 0.5 | 1 |
| Comparative | 100 | 0.1 | 1 | — | — | 1 |
| Example 1 | | | | | | |
| Comparative | 100 | 1 | 1 | — | — | 1 |
| Example 2 | | | | | | |
| Comparative | 100 | 0.1 | 2 | — | — | 1 |
| Example 3 | | | | | | |
| Comparative | 100 | 0.5 | 4 | — | — | 1 |
| Example 4 | | | | | | |
| Comparative | 100 | — | 4 | — | — | 1 |
| Example 5 | | | | | | |
| Comparative | 100 | 10 | 0.5 | 1 | 1 | 1 |
| Example 6 | | | | | | |
| Comparative | 100 | 1 | — | 1 | — | 1 |
| Example 7 | | | | | | |
| Comparative | 100 | — | 12 | 2 | 1 | 1 |
| Example 8 | | | | | | |
| Comparative | 100 | — | 1 | 3 | — | 1 |
| Example 9 | | | | | | |

Adhesive resin (AR): BuRim Chemical, Co., Ltd., BA8900
NIR-A1 (CWO): Sumitomo Metal Mining, YMF-02A (solid content 28.5%, CWO content 18.5%)
NIR-A2 (WO₃): NST, N2B9 (solid content 23%, WO₃ content 15%)
NIR-A3 (near infrared dye): American dye source, NIR949C
NIR-A4 (ITO): DK nano, dk444
PI (curing agent): BuRim Chemical, Co., Ltd., 45S

Manufacture Adhesive Film

A composition manufactured in each of Embodiments 1 through 9 and Comparative Examples 1 through 9 is coated to an anti-reflection-processed PET film to a thickness of 25 μm, and then is heated at 120° C. for five minutes and is cured through aging at 60° C. for three days, thus manufacturing an adhesive film.

### EXPERIMENT EXAMPLE

By evaluating an adhesive strength, a visible transmittance, and a near infrared transmittance of an adhesive film manufactured in each of Embodiments 1 through 9 and Comparative Examples 1 through 9, evaluation results are shown in Table 2.

<Measure Adhesive Strength>

Each adhesive film is attached to non-alkali glass by using a hand roller of 2 kg. After attachment, the adhesive film is left at room temperature for 24 hours and then peeling is performed at 180° at a speed of 300 mm per minute, to measure an adhesive strength.

<Measure Visible Transmittance>

By using a UV-Vis-NIR spectrometer (Perkin Elmer, Lambda 1050+), a transmittance is measured in a wavelength band of 400 nm through 800 nm, and an average value of measured values is recorded as a visible transmittance.

<Measure Near-infrared Transmittance>

By using a UV-Vis-NIR spectrometer (Perkin Elmer, Lambda 1050+), a wavelength-specific transmittance is measured in a wavelength band exceeding 800 nm up to 1500 nm, and an average value of measured values is recorded as a near infrared transmittance.

TABLE 2

| | | | Near Infrared Transmittance (%) | | |
|---|---|---|---|---|---|
| | Adhesive | Visible | Exceeding | Exceeding | Exceeding |
| | Strength | Transmittance (%) | 800 nm up to | 800 nm up to | 1000 nm up to |
| | (gf/inch) | 400 nm~800 nm | 1500 nm | 1000 nm | 1500 nm |
| Embodiment 1 | 1,740 | 84.2 | 19.3 | 20.2 | 12.2 |
| Embodiment 2 | 1,530 | 94.7 | 9.6 | 11.3 | 2.3 |
| Embodiment 3 | 1,430 | 93.2 | 11.8 | 13.9 | 4.5 |
| Embodiment 4 | 1,300 | 94.1 | 12.3 | 13.7 | 4.2 |
| Embodiment 5 | 1,420 | 90.1 | 9.9 | 12.3 | 3.4 |
| Embodiment 6 | 1,170 | 92.8 | 13.3 | 15.6 | 7.2 |
| Embodiment 7 | 1,210 | 88.7 | 25.6 | 26.7 | 17.1 |
| Embodiment 8 | 1,180 | 86.6 | 24.3 | 28.2 | 19.3 |
| Embodiment 9 | 1,250 | 86.7 | 22.1 | 29.1 | 19.4 |
| Comparative | 1,100 | 94.2 | 58.3 | 60.5 | 51.3 |
| Example 1 | | | | | |
| Comparative | 1,700 | 95.3 | 56.3 | 65.3 | 53.6 |
| Example 2 | | | | | |
| Comparative | 1,320 | 76.3 | 26.3 | 29.3 | 18.8 |
| Example 3 | | | | | |
| Comparative | 1,170 | 77.4 | 25.6 | 30.3 | 19.4 |
| Example 4 | | | | | |
| Comparative | 1,330 | 77.1 | 21.1 | 13.3 | 11.4 |
| Example 5 | | | | | |
| Comparative | 800 | 83.2 | 3.6 | 8.3 | 1.3 |
| Example 6 | | | | | |
| Comparative | 1,210 | 93.3 | 53.6 | 60.9 | 50.2 |
| Example 7 | | | | | |
| Comparative | 860 | 80.3 | 3.7 | 8.2 | 1.6 |
| Example 8 | | | | | |
| Comparative | 1,100 | 79.3 | 29.3 | 40.3 | 26.9 |
| Example 9 | | | | | |

Referring to Table 2, the adhesive film manufactured in Embodiments 1 through 9 has a superior adhesive strength and has a transmittance with respect to visible light in a wavelength band of 400 nm through 800 nm and a transmittance with respect to near infrared light in a wavelength band exceeding 800 nm up to 1500 nm, both the visible transmittance and the near infrared transmittance falling within target numerical ranges.

On the other hand, for the adhesive film manufactured in each of Comparative Examples 1 through 9, a transmittance with respect to visible light in a wavelength band of 400 nm through 800 nm or a transmittance with respect to near infrared light in a wavelength band exceeding 800 nm up to 1500 nm does not fall within a target numerical range, resulting in degradation of visibility. Moreover, the adhesive film manufactured in Comparative Examples 6 and 8 has a low adhesive strength, such that the adhesive film may be peeled during a process.

For the adhesive film for the display according to the present invention, a transmittance with respect visible light in a wavelength of 400 nm to 800 nm may be increased and a transmittance with respect near infrared light in a wavelength band exceeding 800 nm up to 1500 nm may be lowered, thereby greatly improving visibility.

Moreover, the adhesive film for the display according to the present invention may have any one or more of a release film, a transparent base film, and glass attached to a surface or both surfaces thereof, thereby reducing light reflected from the adhesive film and removing faint light and thus further improving visibility.

Although the present invention has been described above, the present invention is not limited by the embodiments disclosed herein, and it is apparent that various modifications may be made by those of ordinary skill in the art within the scope of the technical spirit of the present invention. In addition, although the effects of the configuration of the present invention have not been explicitly described while describing the embodiments of the present invention, it is natural that the effects predictable by the configuration should also be recognized.

What is claimed is:

1. An adhesive film for a display, which is manufactured by curing a composition comprising adhesive resin and a near infrared blocking agent,
wherein the adhesive film has a transmittance of 80% or more with respect to visible light in a wavelength band of 400 nm through 800 nm and a transmittance of 5% through 50% with respect to near infrared light in a wavelength band exceeding 800 nm up to 1500 nm.

2. The adhesive film of claim 1, wherein the near infrared blocking agent comprises metal oxide nano powder, near infrared dye, or a combination thereof.

3. The adhesive film of claim 2, wherein the metal oxide nano powder comprises indium tin oxide (ITO), tungsten trioxide (WO₃), cesium-doped WO₃ (CWO), or a combination thereof.

4. The adhesive film of claim 2, wherein the metal oxide nano powder comprises one or more kinds of indium tin oxide (ITO), tungsten trioxide (WO₃), and cesium-doped WO₃ (CWO).

5. The adhesive film of claim 2, wherein the near infrared dye comprises a cyanine-based compound, a phthalocyanine-based compound, a naphthalocyanine-based compound, a porphyrin-based compound, a benzoporphyrin-based compound, a scaryllium-based compound, an anthraquinone-based compound, a croconium-based compound, a dimonium-based compound, a dithiol metal complex, or a combination thereof, and has a maximum absorption wavelength in a wavelength band exceeding 800 nm up to 1200 nm.

6. The adhesive film of claim 1, wherein the adhesive resin comprises urethane resin, acrylic resin, epoxy resin, silicone resin, or a combination thereof.

7. The adhesive film of claim 1, wherein the adhesive film has a transmittance of 10% through 50% with respect to near infrared light in a wavelength band exceeding 800 nm up to 1000 nm.

8. The adhesive film of claim 1, wherein the composition comprises 0.5 to 8 parts by weight of the near infrared blocking agent with respect to 100 parts by weight of the adhesive resin.

9. The adhesive film of claim 1, wherein the composition further comprises 0.1 to 10 parts by weight of a thermosetting agent with respect to 100 parts by weight of the adhesive resin.

10. The adhesive film of claim 1, wherein the composition further comprises 0.1 to 10 parts by weight of a photopolymerization initiator with respect to 100 parts by weight of the adhesive resin.

11. The adhesive film of claim 1, wherein any one or more of a release film, a transparent base film, and glass is further attached to one surface or both surfaces of the adhesive film.

12. The adhesive film of claim 11, wherein the release film is formed on a surface and the other surface of the adhesive film.

13. The adhesive film of claim 11, wherein the release film and the transparent base film are respectively formed one by one on a surface and the other surface of the adhesive film.

14. The adhesive film of claim 11, wherein the transparent base film and the glass are respectively formed one by one on a surface and the other surface of the adhesive film.

15. The adhesive film of claim 11, wherein the transparent base film comprises polyethylene terephthalate (PET), triacetyl cellulose (TAC), cycloolefin polymer (COP), polycarbonate (PC), polyethersulfone (PES), polypropylene (PP), acryl, or a combination thereof.

16. The adhesive film of claim 11, wherein the transparent base film further comprises any one of an anti-reflection layer, a low-reflection layer, and a hard coating layer.

17. The adhesive film of claim 11, wherein the glass further comprises any one of an anti-reflection layer, a low-reflection layer, and a hard coating layer.

18. A display device comprising the adhesive film for the display according to claim 1.
